(19) United States
(12) Patent Application Publication
(10) Pub. No.: US 2008/0029898 A1
(43) Pub. Date: Feb. 7, 2008

(54) VIA STACK STRUCTURES

(76) Inventors: Mukta G. Farooq, Hopewell Junction, NY (US); Robert Hannon, Wappingers Falls, NY (US); Dae Young Jung, LaGrangeville, NY (US); Ian D. Melville, Highland, NY (US); Donna S. Zupanski-Nielsen, Yorktown Heights, NY (US)

Correspondence Address: HOFFMAN, WARNICK & D'ALESSANDRO LLC, 75 STATE ST, 14TH FL, ALBANY, NY, 12207, US

(21) Appl. No.: 11/461,511

(22) Filed: Aug. 1, 2006

(51) Int. Cl. H01L 23/48

(52) U.S. Cl. 257/774

(57) ABSTRACT

Via stack structures are disclosed. In one embodiment, a structure includes a via stack including: a first substantially cross-shaped line in a first dielectric layer; a second substantially cross-shaped line set in a second dielectric layer, and a via stud coupling the first substantially cross-shaped line to the second substantially cross-shaped line. In another embodiment, a structure includes a first via stack, and a second via stack, wherein the first via stack and the second via stack extend in a divergent manner from one another. Each via stack structure is useful for support, for example, in under wire bond applications. The via stack structures can be mixed with other via stack structures and selectively placed within a layout to replace conventional metal plate and via stud array configurations.

### BACKGROUND OF THE INVENTION

1. Technical Field

The invention relates generally to integrated circuit chips, and more particularly, to via stack structures for use therein.

2. Background Art

Wire bond pads are used to couple wires to integrated circuit (IC) chips. Structure under pad (SUP), such as copper line via structures (CLVS), are used under wire bond pads for support. In particular, fragile materials such as ultra low dielectric constant (ULK) materials are used in underlying layers of the wire bond pads. If adequate mechanical support is not provided within these layers, the wire bond pad may pull out or damage the underlying layers. For example, pressure applied during back end of line (BEOL) processes such as electrical probing, wire bonding and associated re-work, can damage the fragile ULK layers. In order to support these materials, via stack structures including metal plates with connecting via studs must be interlocked at all levels. Conventionally, support structures have been localized at the edges and centers of wire bond pads. Typically, these support structures have a large metal plate in one level coupled to another large metal plate in another level by an array of via studs. Unfortunately, these structures consume a large amount of space, which limits the wiring density under the wire bond pads. For example, conventional support structures require 20% via density under the wire bond pad opening. In addition, these structures typically require a designer to route wiring around the structures, which is sometimes difficult to accomplish because of their size.

### SUMMARY OF THE INVENTION

Via stack structures are disclosed. In one embodiment, a structure includes a via stack including: a first substantially cross-shaped line in a first dielectric layer; a second substantially cross-shaped line set in a second dielectric layer, and a via stud coupling the first substantially cross-shaped line to the second substantially cross-shaped line. In another embodiment, a structure includes a first via stack, and a second via stack, wherein the first via stack and the second via stack extend in a divergent manner from one another. Each via stack structure is useful for support, for example, in under wire bond applications. The via stack structures can be mixed with other via stack structures and selectively placed within a layout to replace conventional metal plate and via stud array configurations.

A first aspect of the invention provides a structure comprising: a via stack including: a first substantially cross-shaped line in a first dielectric layer; a second substantially cross-shaped line set in a second dielectric layer; and a via stud coupling the first substantially cross-shaped line to the second substantially cross-shaped line.

A second aspect of the invention provides a structure comprising: a first via stack; and a second via stack, wherein the first via stack and the second via stack extend in a divergent manner from one another.

The illustrative aspects of the present invention are designed to solve the problems herein described and/or other problems not discussed.

### BRIEF DESCRIPTION OF THE DRAWINGS

These and other features of this invention will be more readily understood from the following detailed description of the various aspects of the invention taken in conjunction with the accompanying drawings that depict various embodiments of the invention, in which:

FIG. 1 shows a cross-sectional view of one embodiment of a via stack according to the invention.

FIG. 2 shows a perspective view of part of the embodiment of FIG. 1.

FIG. 3 shows a cross-sectional view of part of an integrated circuit chip employing the via stack structure of FIG. 1 among other via stack structures.

FIG. 4 shows a cross-sectional view of another embodiment of a via stack structure according to the invention.

FIG. 5 shows a cross-sectional view of the embodiment of FIG. 4 employing the via stack structure of FIGS. 1 and 2.

It is noted that the drawings of the invention are not to scale. The drawings are intended to depict only typical aspects of the invention, and therefore should not be considered as limiting the scope of the invention. In the drawings, like numbering represents like elements between the drawings.

### DETAILED DESCRIPTION

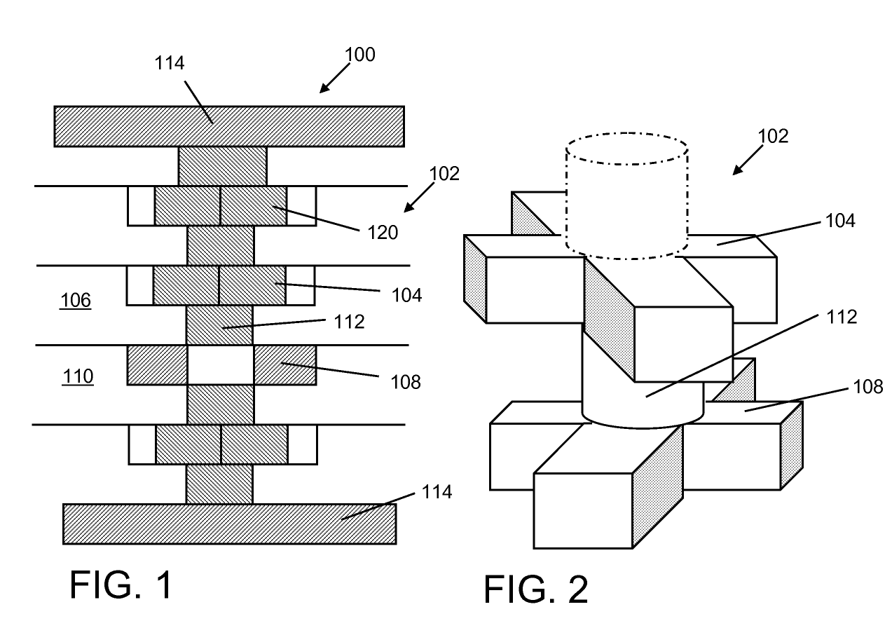

Referring to FIGS. 1-2, one embodiment of a structure 100 (FIG. 1) including a via stack structure 102 is illustrated. Via stack structure 102 includes a first substantially cross-shaped line 104, i.e., wire level line, in a first dielectric layer 106, a second substantially cross-shaped line 108, i.e., wire level line, in a second dielectric layer 110, and a via stud 112 coupling first substantially cross-shaped line 104 to second substantially cross-shaped line 108. Each dielectric layer 106, 110 may include any now known or later developed dielectric material such as silicon nitride (Si₃N₄), silicon oxide (SiO₂), fluorinated SiO₂ (FSG), hydrogenated silicon oxycarbide (SiCOH), porous SiCOH, etc. In addition, although two dielectric layers are illustrated, it should is understood that dielectric layers 106, 110 may be of the same material. The ends of via stack structure 102 couple to anchoring structure 114 such as a wire.

As shown in an upper part of FIG. 1, in one embodiment, adjacent substantially cross-shaped line 104, 120 may be aligned. Alternatively, as shown in a middle part of FIG. 1 and in FIG. 2, substantially cross-shaped line 104 may be set in a first horizontal orientation and an adjacent substantially cross-shaped line 108 may be set in a second horizontal orientation different than the first horizontal orientation. As shown in FIGS. 1 and 2, substantially cross-shaped lines 104, 108 are turned horizontally approximately 45° relative to one another. However, other different orientations are also possible and considered within the scope of the invention. In any event, substantially cross-shaped lines 104, 108, 120 provide a small footprint compared to conventional metal plate and via stud array arrangements. In addition, substantially cross-shaped lines 104, 108, 120 provide improved mechanical integrity than a conventional via stack using via studs due to, inter alia, the lateral extent to which they extend in dielectric 106, 110.

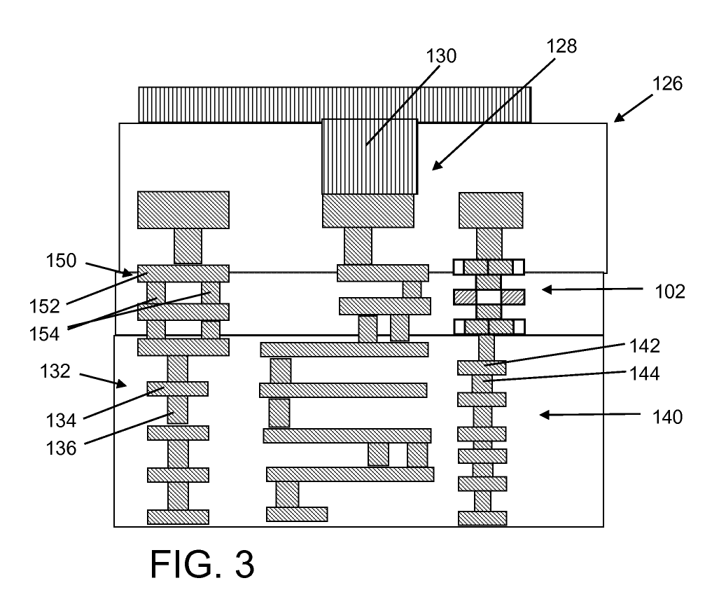

FIG. 3 shows a cross-sectional view of part of an integrated circuit chip 126 including a device 128 employing via stack structure 102 of FIGS. 1-2 among other via stack structures. In this embodiment, device 128 includes a wire bond pad 130; however, the teachings of the invention are not limited to this application. Other via stack structures may include, for example, a first conventional via stack structure 132 including metal plates or wires 134 coupled by via studs 136 in a concentric fashion, and a second conventional via stack structure 140 including via bars 142, 144 positioned substantially perpendicular to one another (i.e., one extends within the plane of the page and another one extends into and out of the plane of the page). FIG. 3 also shows another via stack structure 150 according to one embodiment of the invention including small metal plates 152 coupled by a small array of via studs 154, e.g., four via studs (one pair hidden behind the other).

As illustrated in FIG. 3, via stack structure 102 may be employed with other via stack structures 132, 140, 150 in a selective manner about device 128, both vertically and in the horizontal layout. This is in contrast to conventional techniques that employ a metal plate with an array of via studs about a device. As a result, via stack structures 102, 132, 140, 150 may be mixed and matched to attain maximum support with minimum impact on device performance or wiring integrity, and to minimize chip size. In addition, via stack structures 102, 132, 140, 150 can be positioned within wiring channels and close to devices.

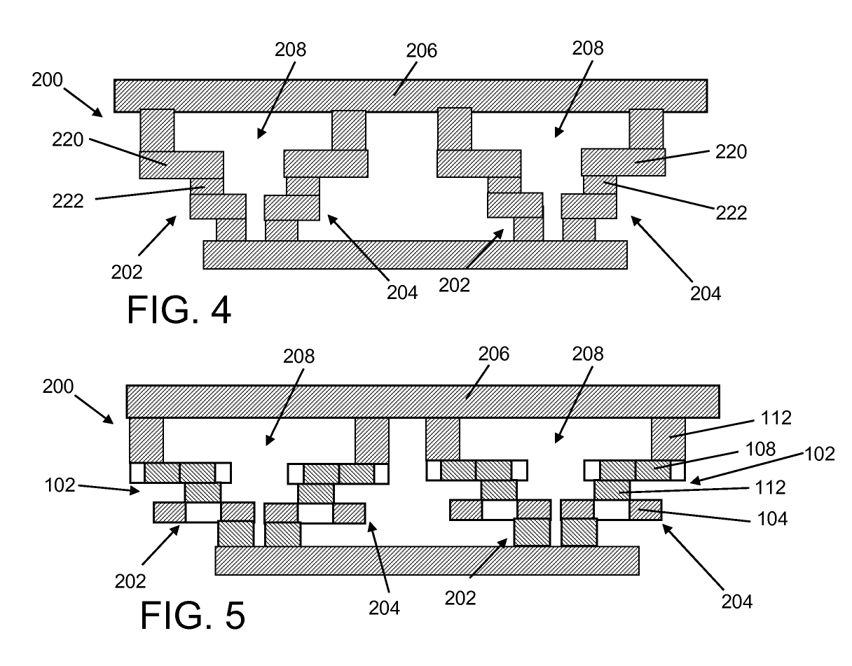

Referring to FIGS. 4-5, another embodiment of a structure 200 is illustrated. Structure 200 may include a first via stack structure 202 and a second via stack structure 204, wherein first via stack structure 202 and second via stack structure 204 extend in a divergent manner from one another. In this manner, via stack structures 202, 204 form a tressel for supporting a structure 206 such as a wire bond pad. As a result, via stack structures 202, 204 open up an interior 208 of, for example, a wire bond pad 206 for wiring. As shown in FIG. 4, in one embodiment, each via stack structure 204, 208 may include conventional metal plates 220 and via studs 222. Alternatively, as shown in FIG. 5, via stacks 202, 204 may employ the above-described via stack 102 including, as shown best in FIGS. 1-2, first substantially cross-shaped line 104 in first dielectric layer 106, second substantially cross-shaped line 108 in second dielectric layer 110, and a via stud 112 coupling first substantially cross-shaped line 104 to second substantially cross-shaped line 108. In this case, however, via stud 112 does not necessarily need to fully land at a center of each cross-shaped line 104. That is, as shown in FIG. 5, via stud 112 may land at a center, or at an end of one part of, substantially cross-shaped line 104, 108. In FIG. 5, first substantially cross-shaped line 104 is shown in a first horizontal orientation and second substantially cross-shaped line 112 is shown in a second horizontal orientation different than the first horizontal orientation. It is understood, however, that they may be aligned, as shown in the upper part of FIG. 1.

Via stack structures 102, 202, 204 may be generated using any now known or later developed methods, e.g., mask deposition, patterning, etching using damascene or dual damascene techniques, etc., deposition of a metal such as copper (Cu), and chemical mechanical polishing, etc. Each part of via stack structures 102, 202, 204 may include a conductive material such as copper (Cu) and any appropriate liners (e.g., tantalum nitride (TaN)) (not shown). As illustrated, the size of each successive layer may enlarge slightly as via stack structures 102, 202, 204 extends/scales upwardly; however, this is not necessary.

The structures described above are used in integrated circuit chips. The resulting integrated circuit chips can be distributed by the fabricator in raw wafer form (that is, as a single wafer that has multiple unpackaged chips), as a bare die, or in a packaged form. In the latter case the chip is mounted in a single chip package (such as a plastic carrier, with leads that are affixed to a motherboard or other higher level carrier) or in a multichip package (such as a ceramic carrier that has either or both surface interconnections or buried interconnections). In any case the chip is then integrated with other chips, discrete circuit elements, and/or other signal processing devices as part of either (a) an intermediate product, such as a motherboard, or (b) an end product. The end product can be any product that includes integrated circuit chips, ranging from toys and other low-end applications to advanced computer products having a display, a keyboard or other input device, and a central processor.

The foregoing description of various aspects of the invention has been presented for purposes of illustration and description. It is not intended to be exhaustive or to limit the invention to the precise form disclosed, and obviously, many modifications and variations are possible. Such modifications and variations that may be apparent to a person skilled in the art are intended to be included within the scope of the invention as defined by the accompanying claims.

What is claimed is:

1. A structure comprising:
a via stack including:
a first substantially cross-shaped line in a first dielectric layer;
a second substantially cross-shaped line set in a second dielectric layer; and
a via stud coupling the first substantially cross-shaped line to the second substantially cross-shaped line.

2. The structure of claim 1, wherein the first substantially cross-shaped line is in a first horizontal orientation and the second substantially cross-shaped line is in a second horizontal orientation different than the first horizontal orientation.

3. The structure of claim 1, further comprising a first plurality of the via stacks and a second plurality of the via stacks, wherein the first plurality of via stacks and the second plurality of via stacks extend in a divergent manner from one another.

4. A structure comprising:
a first via stack; and
a second via stack,
wherein the first via stack and the second via stack extend in a divergent manner from one another.

5. The structure of claim 4, wherein each via stack includes:
a first substantially cross-shaped line in a first dielectric layer;
a second substantially cross-shaped line in a second dielectric layer; and
a via stud coupling the first substantially cross-shaped line to the second substantially cross-shaped line.

6. The structure of claim 5, wherein the first substantially cross-shaped line is in a first horizontal orientation and the second substantially cross-shaped line is in a second horizontal orientation different than the first horizontal orientation.
